(19) United States
(12) Patent Application Publication
(10) Pub. No.: US 2026/0303019 A1
(43) Pub. Date: Oct. 1, 2026

(54) CRYSTAL OSCILLATOR

(71) Applicant: STMicroelectronics International N.V., Geneva (CH)

(72) Inventors: Renald Boulestin, Grenoble (FR); Patrick Simeoni, Voiron (FR)

(21) Appl. No.: 19/577,040

(22) Filed: Mar. 24, 2026

(30) Foreign Application Priority Data
Mar. 27, 2025 (FR) FR2503141

(51) Int. Cl. H03B 5/36

(52) U.S. Cl. CPC H03B 5/36

(57) ABSTRACT

The present description concerns a circuit for controlling a value of a charge capacitor of a crystal oscillator. The circuit receives a target value. The circuit updates a control value from an internal value at each beginning of a period of a clock signal. At each period of the clock signal, the circuit calculates the internal value by adding a modification value to the control value, the modification value being determined by comparing two thresholds with the result of a subtraction of the control value to the operating target value, the thresholds being determined to maintain oscillations at each update of the control value.

### CROSS-REFERENCE TO RELATED APPLICATIONS

This application claims priority to French Patent Application No. 2503141 filed on Mar. 27, 2025, which application is hereby incorporated herein by reference.

### TECHNICAL FIELD

The present disclosure generally concerns integrated electronic circuits, and more particularly the crystal oscillators of these electronic circuits.

### BACKGROUND

Many electronic circuits comprise a crystal oscillator, for example a quartz oscillator, to generate a periodic signal with a period of given value. A crystal oscillator comprises a crystal, such as a quartz crystal, forming part of a loop called, for example, oscillating loop.

A crystal oscillator generally comprises a charge capacitor having a controllable value, a value of the charge capacitor enabling to adjust the frequency of the periodic signal supplied by the crystal oscillator, for example so that the deviation between the current value of the frequency of the periodic signal and a target frequency value is smaller than a threshold.

For example, a first value of the charge capacitor is determined during an initial calibration phase, and then adjusted during the operation of the oscillator. Indeed, variations in the environmental parameters of the crystal oscillator, for example, of the oscillator temperature, alter the frequency of the periodic signal of the crystal oscillator, and the adjustment of the value of the charge capacitor enables to keep the deviation between the value of the frequency and the target value below a threshold.

Known crystal oscillators and known methods in which the oscillator frequency is adjusted by controlling the value of the charge capacitor of the oscillator suffer from various disadvantages.

### SUMMARY

An embodiment circuit for controlling a charge capacitor of a crystal oscillator receives an operating target value. At each clock cycle, the circuit updates and stores a control value from an internal value. The circuit subtracts the control value from the operating target value to produce a subtraction result. The circuit determines a modification value equal to the subtraction result when the subtraction result is between a first positive threshold and a second negative threshold, equal to the first positive threshold when the subtraction result is greater than or equal to the first positive threshold, and equal to the second negative threshold when the subtraction result is smaller than or equal to the second negative threshold. The circuit calculates the internal value by adding the modification value to the control value. The first positive threshold and the second negative threshold share the same absolute value and are chosen so that the ratio gm/gmcrit stays at or above 2 at each update, so that oscillations of the crystal oscillator are maintained.

An embodiment method of controlling a charge capacitor of a crystal oscillator includes a control circuit receiving an operating target value. The control circuit updates and stores a control value from an internal value at each clock cycle. The control circuit subtracts the control value from the operating target value to produce a subtraction result. The control circuit determines a modification value equal to the subtraction result when the subtraction result is between a first positive threshold and a second negative threshold, equal to the first positive threshold when the subtraction result is greater than or equal to the first positive threshold, and equal to the second negative threshold when the subtraction result is smaller than or equal to the second negative threshold. The control circuit calculates the internal value by adding the modification value to the control value. The first positive threshold and the second negative threshold share the same absolute value and ensure the ratio gm/gmcrit stays at or above 2 at each update to maintain oscillations.

An embodiment device includes a control circuit for controlling a value of a charge capacitor of a crystal oscillator. The control circuit includes a register, a subtractor, a saturation circuit, and an adder. The register updates and stores a control value from an internal value at each clock cycle. The subtractor subtracts the control value from an operating target value to produce a subtraction result. The saturation circuit receives the subtraction result from the subtractor and produces a modification value equal to the subtraction result when the subtraction result is between a first positive threshold and a second negative threshold, equal to the first positive threshold when the subtraction result is greater than or equal to the first positive threshold, and equal to the second negative threshold when the subtraction result is smaller than or equal to the second negative threshold. The adder receives the modification value from the saturation circuit and adds it to the control value to produce the internal value. The first positive threshold and the second negative threshold share the same absolute value and are chosen so that the ratio gm/gmcrit stays at or above 2 at each update to maintain oscillations.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, in a simplified view and in the form of blocks, an example of a device comprising a crystal oscillator and being of the type to which the described embodiments and variants apply;

FIG. 2 shows an equivalent electronic circuit of a crystal of a crystal oscillator;

FIG. 3 shows, in a simplified view and in the form of blocks, an embodiment of a circuit for controlling a charge capacitor of a crystal oscillator;

FIG. 4 shows, in a flowchart, an embodiment of a crystal oscillator control method;

FIG. 5 shows, in the form of a block, another embodiment of a circuit for controlling a charge capacitor of a crystal oscillator;

FIG. 6 shows, in a flowchart, another embodiment of a crystal oscillator control method;

FIG. 7 shows, in the form of blocks, a more detailed example of the circuit of FIG. 5 according to an embodiment; and

FIG. 8 shows, in the form of an electronic circuit, an example of embodiment of a circuit of FIG. 7.

### DETAILED DESCRIPTION OF ILLUSTRATIVE EMBODIMENTS

There exists a need to overcome all or part of the disadvantages of known crystal oscillators and of known methods in which the frequency of a crystal oscillator is adjusted by controlling the value of the charge capacitor of the oscillator.

An embodiment overcomes all or part of the disadvantages of known crystal oscillators and of known methods in which the frequency of a crystal oscillator is adjusted by controlling the value of the charge capacitor of the oscillator.

An embodiment provides a circuit for controlling a value of a charge capacitor of a crystal oscillator, configured to: receive an initial target value; receive a signal for starting the crystal oscillator; and as a response to the start-up signal, supply a value for controlling the charge capacitor equal to the initial target value during a first time period. The initial target value is determined so that, during the first time period, a ratio gm/gmcrit is greater than or equal to 5, with gm a transconductance of the crystal oscillator and gmctrit a critical transconductance of the crystal oscillator determined by a current value of the charge capacitor, a frequency of the oscillations, an equivalent series resistance value of a crystal of the crystal oscillator, and a value of the shunt capacitor of the crystal of the crystal oscillator.

An embodiment provides a device comprising the above control circuit, and a first circuit configured to supply an operating target value, the control circuit being further configured to receive the operating target value and, from the end of the first time period, to supply the charge capacitor control value based on the operating target value.

According to an embodiment, the first circuit is configured to supply the initial target value.

An embodiment provides a method of controlling a value of a charge capacitor of a crystal oscillator, comprising the following steps: receiving, with a circuit for controlling the charge capacitor, an initial target value; receiving, with the circuit for controlling the charge capacitor, a signal for starting the crystal oscillator; and as a response to the start-up signal, supplying with the control circuit a charge capacitor control value equal to the initial target value for a first time period. The initial target value is determined so that, during the first time period, a ratio gm/gmcrit is greater than or equal to 5, with gm a transconductance of the crystal oscillator and gmctrit a critical transconductance of the crystal oscillator determined by a current value of the charge capacitor, a frequency of the oscillations, an equivalent series resistance value of a crystal of the crystal oscillator, and a value of the shunt capacitor of the crystal of the crystal oscillator.

According to an embodiment, the method further comprises the supplying of the control circuit with an operating target value with a first circuit, and the supplying, from the end of the first time period and by the control circuit, of the value for controlling the charge capacitor based on the target capacitor operating value.

According to an embodiment, the method further comprises the supply of the initial target value by the first circuit.

According to an embodiment: the control circuit is configured so that, from the end of the first time period, the charge capacitor control value is equal to the operating target value; and the first circuit is configured to determine the initial target value from the operating target value supplied to the control circuit at the end of the first time period, so that when the charge capacitor control value switches from the initial target value to the operating target value, ratio gm/gmcrit remains greater than or equal to 2.

According to an embodiment, the control circuit comprises a second circuit configured, from the end of the first time period, to: receive the operating target value; at each beginning of a period of a clock signal, update and store the value for controlling the value of the capacitor from an internal value of the second circuit; and at each period of the clock signal: subtract the control value from the operating target value, determine a modification value equal to the result of the subtraction if this result lies between a positive first threshold and a negative second threshold, to the first threshold if this result is greater than or equal to the first threshold, and to the second threshold if this result is smaller than or equal to the second threshold, and calculate the internal value by adding the modification value to the control value, wherein the first and second thresholds have a same absolute value determined so that, from the end of the first time period, ratio gm/gmcrit is greater than or equal to 2 at each update of the control value.

According to an embodiment, the control circuit comprises a time delay circuit configured to receive the start-up signal, to trigger a time delay equal to the first time period as a response to the reception of the start-up signal, and to switch a first control signal to a first binary state of the first control signal at the end of the time delay, the control circuit further comprising a circuit configured to supply the charge capacitor control value equal to the initial target value until the switching of the first control signal to the first binary state of the first control signal, and then supply the control value based on the operating target value afterwards.

According to an embodiment, the time delay circuit is configured to trigger a charge of a first capacitor as a response to the start-up signal, to determine the end of the time delay by comparing a voltage across the first capacitor with a first voltage reference, and to couple the first capacitor between a power supply rail and a reference rail at the end of the time delay, so that the first capacitor is used as a power supply decoupling capacitor after the end of the time delay.

According to an embodiment, the start-up signal is a binary signal switching from a first binary state of the start-up signal to a second binary state of the start-up signal at the beginning of a start-up phase of the crystal oscillator and the time delay circuit comprises: a circuit configured to switch a second control signal to a first binary state of the second control signal on switching of the start-up signal to the second state of the start-up signal, and to a second binary state of the second control signal on expiry of a second time period starting with the switching of the start-up signal to the second state of the start-up signal; a first capacitor having a first electrode connected to a reference rail; a circuit configured to compare a voltage on a first node with a first reference voltage; a circuit configured to supply a first charge current to the first capacitor if the voltage of the first node is lower than the first reference voltage and the second control signal is in the second binary state of the second control signal, and to bypass the first capacitor when the second control signal is in the first binary state of the control signal; and a circuit configured to: couple the second electrode of the first capacitor to the first node and isolate the second electrode of the first capacitor from a supply rail if the voltage of the first node is lower than the first reference voltage, and isolate the second electrode of the first capacitor from the first node while holding the voltage on the first node at its current value, and couple the second electrode of the first capacitor to the power supply rail if the voltage of the first node is greater than the first reference voltage. The first control signal switches to the first binary state of the first control signal when the voltage on the first node becomes greater than the first reference voltage.

An embodiment provides a circuit for controlling a value of a charge capacitor of a crystal oscillator, configured to: receive an operating target value; at each beginning of a period of a clock signal, update and store a value for controlling the capacitor value from an internal value of the circuit; and at each period of the clock signal: subtract the control value from the operating target value, determine a modification value equal to the result of the subtraction if this result lies between a positive first threshold and a negative second threshold, to the first threshold if this result is greater than or equal to the first threshold, and to the second threshold if this result is lower than or equal to the second threshold, and calculate the internal value by adding the modification value to the control value. The first and second thresholds have a same absolute value determined so that oscillations of the crystal oscillator are maintained at each update of the control value, the oscillations being maintained when a ratio gm/gmcrit is greater than or equal to 2, with gm a crystal oscillator transconductance and gmctrit a critical crystal oscillator transconductance determined by a current value of the charge capacitor, a frequency of the oscillations, an equivalent series resistance value of a crystal of the crystal oscillator, and a value of the shunt capacitor of the crystal of the crystal oscillator.

An embodiment provides a method of controlling a value of a charge capacitor of a crystal oscillator, comprising the following steps: receiving, by a control circuit, an operating target value; at each beginning of a period of a clock signal, updating and storing with the control circuit a value for controlling the capacitor value from an internal value of the control circuit; and at each period of the clock signal: subtracting the control value from the operating target value with the control circuit, determining with the control circuit a modification value equal to the result of the subtraction if this result lies between a first positive threshold and a second negative threshold, to the first threshold if this result is greater than or equal to the first threshold, and to the second threshold if this result is lower than or equal to the second threshold, and calculating the internal value by adding the modification value to the control value with the control circuit. The first and second thresholds have a same absolute value, so that oscillations of the crystal oscillator are maintained at each update of the control value, the oscillations being maintained when a ratio gm/gmcrit is greater than or equal to 2, with gm a crystal oscillator transconductance and gmctrit a critical crystal oscillator transconductance determined by a current value of the charge capacitor, a frequency of the oscillations, an equivalent series resistance value of a crystal of the crystal oscillator, and a value of the shunt capacitor of the crystal of the crystal oscillator.

According to an embodiment, critical transconductance gmcrit is a minimum value of transconductance gm of the crystal oscillator to obtain oscillations across the crystal oscillator.

According to an embodiment, the charge capacitor of the crystal oscillator comprises two identical capacitors with adjustable values, connected to the respective terminals of the crystal of the crystal oscillator.

According to an embodiment, the value of each of the two adjustable capacitors is selected from a plurality of discrete values determined by an adjustment step.

According to an embodiment: the value of the charge capacitor is selected from a plurality of discrete values, each two successive discrete values of the charge capacitor being separated from each other by a constant step; the operating target value is equal to one of the discrete values of the charge capacitor; and the first and second thresholds have an absolute value equal to an integer multiple of the constant step.

According to an embodiment, the operating target value, the control value, the internal value, the result of the subtraction, and the modification value are digital signals.

An embodiment provides a device comprising: a crystal oscillator; a charge capacitor of the crystal oscillator; and the control circuit such as defined hereabove.

An embodiment provides a device comprising: a crystal oscillator; a charge capacitor of the crystal oscillator; and the control circuit such as defined above when the charge capacitor value is selected from a plurality of discrete values separated from one another by a constant step. The operating target value, the control value, the internal value, the result of the subtraction, and the modification value are digital signals. The control value is coded in natural binary, the control circuit further comprising a conversion circuit configured to supply, from the natural binary-coded control value, a gray-coded digital control signal or a thermometric digital control signal to the charge capacitor.

According to an embodiment, the conversion circuit is configured to supply the gray-coded digital control signal, the absolute value of the first and second thresholds being equal to said constant step.

According to an embodiment, the crystal oscillator comprises the crystal and a resistive feedback inverter forming an oscillating loop of the crystal oscillator.

The same elements have been designated by the same The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, the known electronic systems and circuits in which a periodic signal is generated from a crystal oscillator have not been described, the embodiments and variants described herein being compatible with these known electronic systems and circuits.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

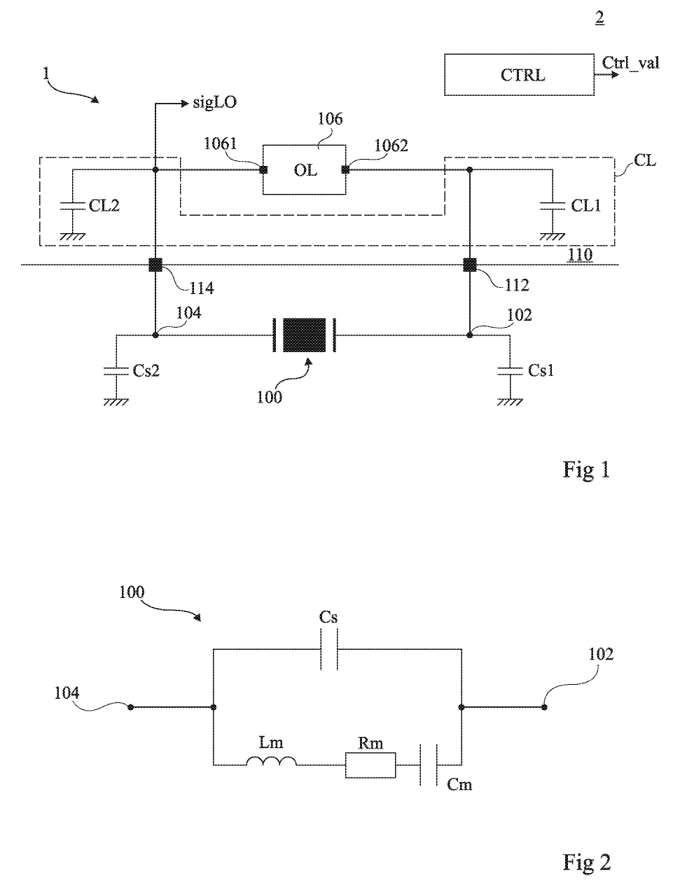

FIG. 1 shows, in a simplified view and in the form of blocks, an example of a device 2 of the type to which the described embodiments and variants apply.

Device 2 comprises a crystal oscillator 1.

Crystal oscillator 1 comprises a crystal 100, for example a quartz crystal.

Crystal 100 has a first terminal or electrode 102 and a second terminal or electrode 104.

Crystal 100 is connected to a circuit 106 (block "OL" in FIG. 1) of oscillator 1. Crystal 100 and circuit 106 form together a loop of crystal oscillator 1. Circuit 106 is a resistive feedback inverter. For example, the electrode 104 of crystal 100 is coupled, for example connected, to an output 1061 of circuit 106, and an input 1062 of circuit 106 is coupled, for example connected, to the electrode 102 of crystal 100. As an example, circuit 106 implements an inverting function between its input 1062 and its output 1061.

Oscillator 1 further comprises a charge capacitor CL, delimited by dotted lines in FIG. 1. Capacitor CL is connected to crystal 100.

Capacitor CL is an adjustable capacitor. In other words, the value of capacitor CL is controlled by a signal Ctrl_val. Signal Ctrl_val indicates the value for controlling capacitor CL. Signal Ctrl_val is preferably a digital signal. Capacitor CL is, for example, a capacitor having its current value selected, by signal Ctrl_val, from a plurality of discrete values, each two successive discrete values of capacitor CL being separated from each other by a constant step CL0. For example, capacitor CL can take any of N+1 discrete values equal to i*CL0, where i is an integer ranging from 0 to N.

Preferably, capacitor CL is implemented by two adjustable capacitors CL1 and CL2 identical to each other. Each of the two capacitors CL1 and CL2 is, for example, a capacitor having its current value selected, by signal Ctrl_val, from a plurality of discrete values, each two successive discrete values of capacitor CL1, CL2 being separated from each other by a constant adjustment step C0, for example equal to a unit capacitor value, for example equal to 2.CL0. For example, each of the two capacitors CL1 and CL2 can take any of N+1 discrete values equal to i*C0, where i is an integer ranging from 0 to N.

Capacitors CL1 and CL2 are connected to the respective terminals 102 and 104 of crystal 100. For example, capacitor CL1 has one terminal or electrode connected to terminal 102, the other terminal of capacitor CL1 being, for example, connected to a reference potential, for example ground. Symmetrically, capacitor CL2 has, for example, one terminal or electrode connected to terminal 104, the other terminal of capacitor CL2 being, for example, connected to the reference potential.

In the example of FIG. 1, parasitic capacitors Cs1 and Cs2 have been shown, these capacitors Cs1 and Cs2 corresponding, for example, to the parasitic capacitors of the connections between crystal 100 and capacitors CL1 and CL2. Preferably, the connections of crystal 100 to capacitors CL1 and CL2 and to circuit 106 are implemented so that capacitors Cs1 and Cs2 have identical capacitor values. As an example, capacitor Cs1 is connected to terminal 102 and represents all the parasitic capacitors on this terminal 102, while capacitor Cs2 is connected to terminal 104 and represents all the parasitic capacitors on this terminal 104. As an example, each of capacitors Cs1 and Cs2 has a maximum value equal to 3 pF.

Oscillator 1 supplies an output signal sigLO. When oscillations are present across crystal 100, periodic signal sigLO has a frequency F. Signal sigLO is available on one of the terminals of crystal 100, for example on terminal 104.

To adjust frequency value F to a given target value, device 2 comprises a control circuit CTRL configured to control the value of capacitor CL, that is, the value of each of capacitors CL1 and CL2. Thus, circuit CTRL is configured to supply a value for controlling the value of capacitor CL, or, in other words, to supply a signal Ctrl_val indicating the value for controlling the value of capacitor CL.

As an example, circuit CTRL is configured to receive an indication of the temperature of device 1, and to supply the value Ctrl_val for controlling the value of capacitor CL, for example from a table of correspondence between the temperature and a target value Ctrl_target that capacitor CL must take so that the frequency F of signal sigLO is equal to a target frequency value. As an example, value Ctrl_target is equal to one of the discrete values that charge capacitor CL can take.

In practice, the frequency F of the oscillations decreases as the value of capacitor CL increases.

In the example of FIG. 1, capacitor CL and circuit CTRL form part of an integrated circuit chip 110, and crystal 100 is located outside this chip 110. For example, chip 110 comprises two connection pads 112 and 114, having the respective terminals 102 and 104 connected thereto. In this case, the output 1061 of circuit 106 is coupled, for example connected, to pad 114, the input 1062 of circuit 106 is coupled, for example connected, to pad 102, capacitor CL2 is connected to pad 114, and capacitor CL1 is connected to pad 112.

When signal sigLO is supplied by oscillator 100, that is, when oscillations are present across crystal 100, a problem of device 2 and, more particularly, of its circuit CTRL, is that a change in value Ctrl_val can result in an oscillation loss, that is, in a stopping of oscillations. A change in value Ctrl_val is implemented, for example, to compensate for a variation in frequency F with respect to its target value which results, for example, from a change in the temperature of device 2. A change in value Ctrl_val is, for example, implemented to set frequency F to its target value after a start-up phase of device 2, that is, after a start-up phase at the end of which oscillations are present in oscillator 1.

Although this is not illustrated in FIG. 1, usually, device ma1y comprise an amplitude loop control circuit configured to regulate the amplitude of signal sigLO.

FIG. 2 shows, in the form of an electrical circuit, a circuit equivalent to the crystal 100 of FIG. 1.

Crystal 100 is equivalent, between its two electrodes 102 and 104, to a shunt capacitor Cs connected between terminals 102 and 104 and in parallel with a series combination of an inductance Lm, a resistor Rm, and a capacitor Cm. For example, capacitor Cs has one terminal or electrode coupled, preferably connected, to terminal 102, and one terminal or electrode coupled, preferably connected, to terminal 104. As an example, resistor Rm is an equivalent series resistance of crystal 100. As an example, elements Lm, Rm, and Cm are series-connected between terminals 102 and 104, the branch comprising elements Cm, Lm, and Rm comprising no other elements between terminals 102 and 104.

By applying the above model to the oscillator 1 of FIG. 1, for oscillations to occur across crystal 100, the transconductance gm of circuit 106, also called, for example, transconductance of oscillator 1, needs to be equal to or greater than a critical transconductance gmcrit. Critical transconductance gmcrit is determined by the value of charge capacitor CL, the frequency F of the oscillations, the value of the equivalent series resistance Rm, and the value of shunt capacitor Cs. For example, critical transconductance gmcrit is determined by the following equation: gmcrit = 4.ESR.(2.π.F)².(Cs+CL)², with ESR a value determined by resistance Rm, for example considered equal to the value of resistance Rm. Assuming that capacitors CL1 and CL2 have a same value, the above equation can be written: gmcrit = 4.ESR.(2.π.F)².(Cs+CL1/2)²

Critical transconductance gmcrit thus depends on the current value of capacitor CL, and thus, for example, on the current value of capacitor CL1, which is the same as that of capacitor CL2, and on the value of the frequency F of the oscillations between the terminals 104 and 102 of crystal 100, that is, on the value of the frequency F of the oscillations in crystal oscillator 1.

There is considered as an example a first steady state where capacitor CL has a value CLA and where the stable oscillations of signal sigLO have a frequency F of value FA, and a second steady state where capacitor CL has a value CLB and where the stable oscillations of signal sigLO have a frequency F of value FB. Critical transconductance gmcrit has a value gmcritA in the first steady state and a value gmcritB in the second steady state. To switch from the first steady state to the second steady state, the value of capacitor CL is switched from value CLA to value CLB. This results in a transient state in which the value of capacitor CL varies at a rate different from that of the value of frequency F, which impacts the value of the critical transconductance during the transient. Indeed, the transconductance gm of circuit 106 is considered constant, for example for a given bias current of circuit 106. As a result, for example, during this transient, the frequency F of the oscillations may still be equal to FA, while the value of capacitor CL may already be equal to CLB. As a result, when value CLA is lower than value CLB, critical transconductance gmcrit may first increase from value gmcritA, for example, up to a value gmcritmax corresponding to a capacitor CL of value CB and a frequency F of value FA, and then decrease to value gmcritB. Thus, during this variation of critical transconductance gmcrit, transconductance gm may no longer be sufficient for oscillations to be maintained in oscillator 1, and signal sigLO may stop oscillating, which poses a problem.

According to a first aspect, there is provided, on switching from a first value to a second value of the charge capacitor, that the transition from the first value to the second value takes place via one or more intermediate values of capacitor CL, with a clock signal which clocks the update of each value for controlling the value of capacitor CL, and with a maximum value of change of the control value between two successive cycles of the clock signal which enables to maintain a ratio gm/gmcrit in oscillator 1 which is greater than or equal to 2 during each change between two successive control values of the value of capacitor CL. Indeed, keeping ratio gm/gmcrit greater than or equal to 2 at each change in the value of capacitor CL enables to ensure the maintaining of stable oscillations across oscillator 100.

In other words, it is here provided to limit to a threshold TH the maximum change in the capacitor value that can be applied to capacitor CL in one clock signal cycle, so that ratio gm/gmcrit remains greater than or equal to 2, even during the transient resulting from the change in value of capacitor CL. In particular, transconductance gm is, for example, considered constant for a given bias current of circuit 106. Since the value of the bias current is known, the value of transconductance gm is known. For example, the constant value of transconductance gm is determined as being the worst value, that is, the lowest value, that transconductance gm can take during a simulation in which the temperature, the value of the variations resulting from the manufacturing process, and the value of a power supply voltage of device 1 are varied, that is, a PVT (Process, Voltage, Temperature) simulation.

More generally, those skilled in the art will be capable, in the light of the present disclosure, of determining the constant value of transconductance gm to be used to calculate ratio gm/gmcrit and of verifying that this ratio remains greater than or equal to 2.

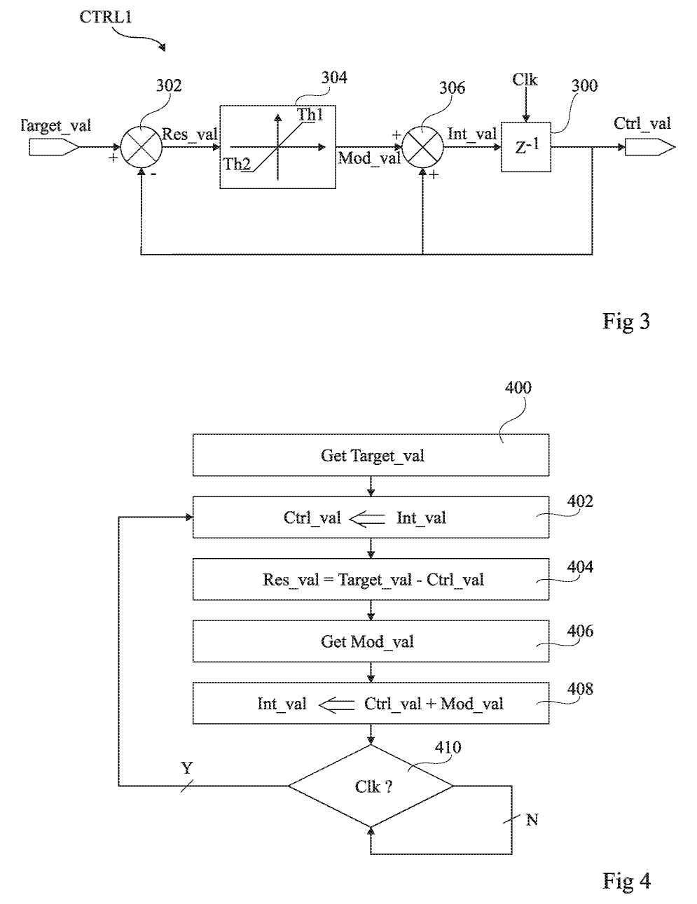

FIG. 3 shows, in a simplified view and in the form of blocks, an embodiment of a circuit CTRL1 for controlling the charge capacitor of a crystal oscillator, for example, of the oscillator 1 of device 2. For example, according to an embodiment, circuit CTRL1 is used as a replacement for circuit CRTL in the device 2 of FIG. 1, and is configured to control the value of capacitor CL.

Circuit CTRL1 is configured to receive a target value Target_val for the value of capacitor CL, and to supply, to capacitor CL, control value Ctrl_val. As an example, the target value Ctrl_target of capacitor CL is supplied to circuit CTRL1 by a circuit of device 2, not shown in FIG. 1. This circuit for supplying target value Ctrl_target is, for example, configured to receive a value for the temperature of the device 2, and to supply a corresponding target value Val_target so that, when capacitor CL has value Val_target at this temperature, frequency F is equal to its target frequency value, to within a given maximum deviation, for example equal to 5 ppm (parts per million) of this target frequency value.

Circuit CTRL1 receives a clock signal Clk clocking the operation of circuit CTRL1.

At each beginning of a cycle, or period, of clock signal Clk, circuit CTRL1 updates value Ctrl_val from an internal value Int_val of circuit CTRL1. In other words, at the beginning of each cycle of signal Clk, value Ctrl_val receives value Int_val. Further, once value Ctrl_val has been updated, value Ctrl_val is stored until the beginning of the next cycle of signal Clk. In other words, between two successive updates, value Ctrl_val is kept constant.

These two functions of update of value Ctrl_val from value Int_val and of storage of value Ctrl_val at the beginning of each cycle of signal Clk are schematically shown in FIG. 3 by a block 300 (block "Z⁻¹") which receives signal Clk and value Int_val, and which supplies value Ctrl_val. As an example, block 300 is implemented by a synchronous register receiving value Int_val on its data input and signal Clk on its clock input, and supplying value Ctrl_val on its output. As an example, register 300 is implemented by D flip-flops.

Further, circuit CTRL1 is configured, at each period of signal Clk, that is, between each two successive updates of value Ctrl_val, to calculate the value Int_val which will be used for the next update of value Ctrl_val. This value Int_val is calculated from value Target_val, value Ctrl_val, and two thresholds Th1 and Th2 having the same absolute values and being respectively positive and negative.

More particularly, circuit CTRL1 is configured, at each cycle of signal Clk, to subtract control value Ctrl_val from target value Target_val, a value equal to the result of this subtraction being designated with reference Res_val in FIG. 3. In FIG. 3, the function of subtraction of value Target_val from value Target_val is shown in the form of a subtractor block 302 receiving values Target_val and Ctrl_val and supplying value Res_val.

Circuit CTRL1 is configured to apply a symmetrical saturation function, that is,, centered on 0, to the result Res_val of the subtraction to determine a modification value Mod_val. As an example, circuit CTRL1 determines the value Mod_val as follows: - value Mod_val is equal to value Res_val if value Res_val lies between the two thresholds Th1 and Th2; - value Mod_val is equal to threshold Th1 if value Res_val is greater than or equal to threshold Th1; and - value Mod_val is equal to threshold Th2 if value Res_val is smaller than or equal to threshold Th2.

In FIG. 3, the application of the saturation function to value Res_val to obtain value Mod_val is shown in the form of a block 304 illustrating the course of the saturation function between thresholds Th1 and Th2. Block 304 receives value Res_val and supplies the corresponding value Mod_val.

Thresholds Th1 and Th2, that is, the absolute value common to the two thresholds Th1 and Th2, are determined in such a way that a change in the value of capacitor CL occurring within one cycle of signal Clk and having a value a range from Th2 to Th1 makes it possible to maintain a ratio gm/gmcrit greater than or equal to 2 in oscillator 1, for example, in particular when the transconductance gm of circuit 106 is constant, for example, because the bias current of circuit 106 is constant. As an example, thresholds Th1 and Th2 are determined by a designer of device 2 taking into account the frequency of signal Clk, so that at each update of value Ctrl_val, ratio gm/gmcrit is greater than or equal to 2 in oscillator 1.

Internal value Val_int is calculated, by circuit CTRL1, from value Mod_val and value Ctrl_val. More particularly, circuit CTRL1 is configured to calculate value Int_val, and value Int_val is equal to the sum of value Ctrl_val and of value Mod_val. In FIG. 3, this function of addition of value Mod_val to the current value of value Ctrl_val to obtain the internal value Int_val is shown in the form of an adder block 306 receiving values Ctrl_val and Mod_val and supplying value Int_val.

Preferably, values Target_val, Res_val, Mod_val, Int_val, and Ctrl_val are digital signals, for example digital signals encoded in natural binary. In other words, each of values Target_val, Res_val, Mod_val, Int_val, and Ctrl_val is represented as a binary digital signal, for example encoded in natural binary. In this case, circuit CTRL1 is a particularly simple to implement digital circuit. For example, subtractor block 302 and adder block 306 may each be implemented by a digital adder circuit.

The use of digital signals for values Target_val, Res_val, Mod_val, Int_val, and Ctrl_val is also particularly adapted to the case where the value of capacitor CL is selected, by signal Ctrl_val, from among a plurality of discrete values, and where, within this plurality of discrete values, each two successive discrete values are separated from each other by constant step CL0. Indeed, when values Target_val, Res_val, Mod_val, Int_val, and Ctrl_val each correspond to a binary digital signal, for example coded in natural binary, these values then are discrete values.

As an example, when the value of capacitor CL is selected from among a plurality of discrete values determined by constant step C0, the absolute value of thresholds Th1 and Th2 is then equal to an integer multiple of this step C0.

Although this is not shown in FIG. 3, when the value CTRL_val available at the output of block 300 is a digital signal coded in natural binary, or, in other words, when the value CTRL_val available at the output of block 300 is coded in natural binary, circuit CTRL1 may comprise a conversion circuit configured to supply, from value CTRL_val coded in natural binary, a gray- or thermometric-coded control value CTRL_val. In other words, the conversion circuit is configured to supply charge capacitor CL with a gray-coded digital control signal CTRL_val or a thermometric digital control signal CTRL_val from the signal of the natural binary-coded control value CTLR_val.

As a more specific example, when the control signal CTRL_val received by charge capacitor CL is a gray-coded digital signal, the absolute value of thresholds Th1 and Th2 is preferably selected to be equal to the value of constant step C0. Thus, at each cycle of signal Clk, the value of capacitor CL is at most modified by a value of +C0 or -C0. As a result, for each cycle of signal Clk, at most a single bit of signal CTRL_val changes binary value. Since each of the two capacitors CL1 and CL2 is generally implemented by the parallel connection of a plurality of series associations of a capacitor and of a switch controlled by a bit of signal CTRL_val, this means that, at each cycle of signal Clk, there is only one switch of each of capacitors CL1 and CL2 which switches between the off and on states. As an example, in such an implementation of each of the two capacitors CL1 and CL2, the capacitors each associated in series with a corresponding switch have values different from one another corresponding to P different values 2^{j}.C0, with j an integer index ranging from 0 to P-1 and P an integer number greater than 1. In such an example, each capacitor CL1, CL2 can then take 2^{P} different discrete values.

FIG. 4 shows, in a flowchart, an embodiment of a method of controlling a crystal oscillator. For example, FIG. 4 illustrates steps of the method of controlling the charge capacitor CL of the oscillator 1 of device 2 with the circuit CTLR1 described in relation with FIG. 3.

At a step 400 ("Get Target_val" block), control circuit CTRL1 receives target value Target_val.

At a step 402 (block "Ctrl_val <= Int_val"), implemented at the beginning of each cycle of signal Clk, circuit CTRL1 updates control value Ctrl_val from its internal value Int_val, then stores the updated value Ctrl_val until the beginning of the next cycle of signal Clk.

At a next step 404 (block "Res_val = Target_val - Ctrl_val"), circuit CTRL1 subtracts value Ctrl_val from value Target_val.

At a next step 404 (block "Res_val = Target_val - Ctrl_val"), circuit CTRL1 subtracts value Ctrl_val from value Target_val.

At a next step 406 ("Get Mod_val" block), circuit CTRL1 determines value Mod_val by applying saturation function 304 to value Res_val.

At a next step 408 (block "Int_val Ctrl_val <= + Mod_val"), circuit CTRL1 calculates the internal value Int_val by adding value Mod_val to value Ctrl_val.

In practice, steps 402, 404, 406 and 408 are implemented at each cycle of signal Clk, step 402 being implemented at the beginning of the cycle. For example, steps 402, 404, 406, and 408 are implemented at each cycle Clk following a start-up phase of oscillator 1, at the end of which oscillations are present in oscillator 1.

Thus, at a next step 410 (block "Clk?"), while all steps 402 to 408 have been implemented during the current cycle of signal Clk, circuit CTRL1 waits for the beginning of the next cycle of signal Clk (output N of block 410). As soon as this next cycle begins (output Y of block 410), the method continues at step 402 and steps 402 to 408 are implemented for this next cycle.

Although this has not been shown in relation with FIG. 3, preferably, in circuit CTRL1 and in the method described in relation with FIG. 4, changes in value Target_val are synchronized with signal Clk. For example, value Target_val may only change at the beginning of a cycle of signal Clk, at the same time as value Ctrl_val is updated.

There has been described hereabove, in a first aspect, an embodiment of a control circuit CTRL1 and a method of controlling the charge capacitor CL of an oscillator 100 of a device 1, enabling, during a change in the target value Target_val of the capacitor, for the change in value of capacitor CL to maintain a ratio gm/gmcrit greater than or equal to 2. This enables to maintain stable oscillations across crystal 100, that is, stable oscillations of signal sigLO.

Apart from the issue of oscillation loss in device 2 during a change in value of charge capacitor CL, another problem of device 2 concerns the start-up phase of its oscillator 1.

Indeed, at the start-up of oscillator 1, that is, for example, when the bias current of circuit 106 changes from a zero value to a non-zero value, for signal sigLO to start oscillating, oscillator 1 needs to meet the Barkhausen criteria. For example, at the start-up of oscillator 1, circuit 106 amplifies noise present in the loop comprising circuit 106 and crystal 100, and the amplified signal is supplied to crystal 100, which acts as a filter. When the Barkhausen criteria are met, this results in that, progressively, stable oscillations are established in oscillator 1.

The compliance with these criteria can be complex to implement. Further, the compliance with these criteria can lead to circuits having large surface areas. For example, at the start-up of oscillator 1, it is generally provided to increase the bias current of circuit 106, in such a way as to ensure that the noise amplification in the loop allows the starting of the oscillations. This amounts to increasing the transconductance gm in oscillator 1 during its start-up phase. However, for circuit 106 to be able to withstand a higher bias current during its start-up phase than during an operating phase, its transistors, for example MOS (Metal Oxide Semiconductor) transistors, need to have higher W/L aspect ratios. Now, it is also generally desirable to increase the L dimension of these transistors to decrease flicker noise. This results in transistors having large surface areas, and in a bulky device 2.

According to a second aspect, it is provided, at the start-up of oscillator 1, to control charge capacitor CL to a value such that ratio gm/gmcrit is greater than or equal to 5, for the entire duration of the start-up phase, this duration being fixed and, preferably, programmable. Preferably, during this start-up phase, the bias current of circuit 106 has the same value as when oscillator 1 is in steady state, or, in other words, the start-up phase is implemented without increasing the bias current of circuit 106. This enables to keep the surface area of device 2 relatively small as compared with the case where the bias current of circuit 106 is increased during the start-up phase. Further, the provision of a ratio gm/gmcrit greater than or equal to 5 enables to ensure that stable oscillations are established in oscillator 1 during its start-up phase.

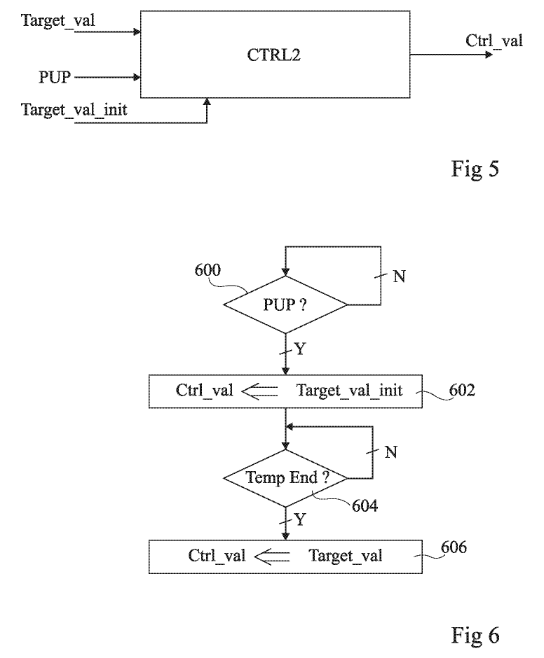

FIG. 5 shows, in the form of a block, another embodiment of a circuit CTRK2 for controlling a charge capacitor of a crystal oscillator, for example the charge capacitor CL of the oscillator 1 of the device 2 of FIG. 1. For example, according to an embodiment, circuit CTRL2 is used as a replacement for circuit CRTL in the device 2 of FIG. 1, and is configured to control the value of capacitor CL.

Circuit CTRL2 is configured to receive an initial target value Target_val_init of capacitor CL. Circuit CTRL2 is further configured to receive a signal PUP for starting oscillator 1. For example, signal PUP is a binary signal which indicates by a switching, for example from a first binary state of signal PUP to a second state of signal PUP, that oscillator 1 is in a start-up phase. In other words, a switching of signal PUP, for example from the first binary state of signal PUP to the second state of signal PUP, indicates the beginning of a start-up phase of oscillator 1. As an example, signal PUP is supplied by a circuit not shown in FIG. 1. As an example, signal PUP indicates the beginning of a start-up phase when oscillator 1 is powered on, that is, for example, the time when a non-zero bias current starts being supplied to oscillator 1, for example to its circuit 106.

As a response to start-up signal PUP, circuit CTRL2 is configured to supply control value Ctrl_val to capacitor CL equal to the initial target value Target_val_init for a time period Tstart. Time Tstart is equal to the duration of the start-up phase of oscillator 1. As an example, this duration is programmable.

Value Target_val_init is determined in such a way that, during the entire time period Tstart, while capacitor CL is controlled by control value Ctrl_val to have a value equal to value Target_val_init, ratio gm/gmcrit is greater than or equal to 5.

As an example, value Target_val_init is supplied to circuit CTRL2 by a circuit not shown in FIG. 1, for example in the form of a digital signal encoding value Target_val_init.

As an alternative example, value Target_val_init is received by circuit CTRL2 during its design phase, and is hard-coded in circuit CTRL2. This is the case, for example, when value Target_val_init is equal to a zero value, or when value Target_val_init is the same regardless of the control value Ctrl_val of capacitor CL once the start-up phase is over.

According to an embodiment, so that circuit CTRL2 can control the value of capacitor CL once the start-up phase of oscillator 1 is over, circuit CTRL2 is further configured to receive an operating target value Target_val for the value of capacitor CL. As with the previously-described circuit CTRL1, this value Target_val is, for example, supplied to circuit CTRL2 by a circuit not shown in FIG. 1. As an example, the circuit supplying value Target_val may be the same as that supplying value Target_val_init.

In such an embodiment, from as soon as the end of the start-up phase of oscillator 1, circuit CTRL2 is configured so that the control value Ctrl_val that it supplies to capacitor CL is no longer equal to value Target_val_init, but is determined by the value Target_val that circuit CTRL2 receives, for example so that value Ctrl_val is equal to the value Target_val received.

In other words, in such an embodiment, circuit CTRL2 is configured, from the end of the start-up phase of duration Tstart, to supply Ctrl_val value based on the operating target value Target_val.

The operation of above-described circuit CTRL2 corresponds to the method illustrated in FIG. 6.

FIG. 6 shows, in a flowchart, an embodiment of a method of controlling a crystal oscillator, for example, implemented by circuit CTRL2, for example in the device 2 of FIG. 1, where circuit CTRL2 replaces circuit CTRL.

At step 600 (block "PUP?" in FIG. 6), circuit CTRL2 waits for the signal for starting oscillator 1, that is, waits for the indication of beginning of the start-up phase of duration Tstart.

As long as start-up signal PUP has not been received, that is, as long as no indication that a start-up phase is beginning has not been received, circuit CTRL2 remains in step 600 (output N of block 600).

When circuit CTRL2 receives start-up signal PUP (output Y of block 600), that is, for example, the switching of signal PUP to its second binary state, the method continues to a step 602 (block "Ctrl_val <= Target_val_init" in FIG. 6) where circuit CTRL2 supplies control value Ctrl_val equal to the initial target value Target_val_init. As an example, this value Target_val_init is received by circuit CTRL2 during step 600 or at the beginning of step 602 and is, for example, supplied to circuit CTRL2 by another circuit. As an alternative example, this value Target_val_init is determined on design of circuit CTRL2 and received by circuit CTRL2 during its manufacture, for example by being programmed in circuit CTRL2 or by being hard-coded in circuit CTRL2.

Further, at step 602, circuit CTRL2 starts a time delay of duration Tstart. More particularly, as a response to the reception of start-up signal PUP, circuit CTRL2 starts the time delay of duration Tstart.

At a next step 604 ("Temp End ?" block in FIG. 6), while circuit CTRL2 is still supplying control value Ctrl_val equal to the initial target value Target_val_init, circuit CTRL2 determines whether the time delay has ended, or, in other words, whether time period Tstart has elapsed since circuit CTRL2 has begun supplying control value Ctrl_val equal to the initial target value Target_val_init.

If time delay Tstart has not ended (output N of block 604), circuit CTRL2 keeps on supplying value Ctrl_val equal to value Target_val_init.

However, if time delay Tstart is over (output Y of block 604), then the start-up phase is over.

Time period Tstart is determined in such a way that, at the end of time period Tstart, and having controlled capacitor CL to value Target_val_init for the entire time period Tstart, stable oscillations have been established in oscillator 1. Those skilled in the art will be capable, for example based on the results of simulations of oscillator 1, for example performed with the software designated with trade name Cadence, to determine the value of duration Tstart.

According to an embodiment, as shown in FIG. 6, after the end of the start-up phase, that is, after step 604, the method continues to a step 606 (block "Ctrl_val <= Target_val_init" in FIG. 6) where circuit CTRL2 supplies the control value Ctrl_val of capacitor CL by determining this control value Ctrl_val from the operating target value Target_val, for example supplied by a circuit not shown in the device 2 of FIG. 2 where circuit CTRL2 replaces circuit CTRL.

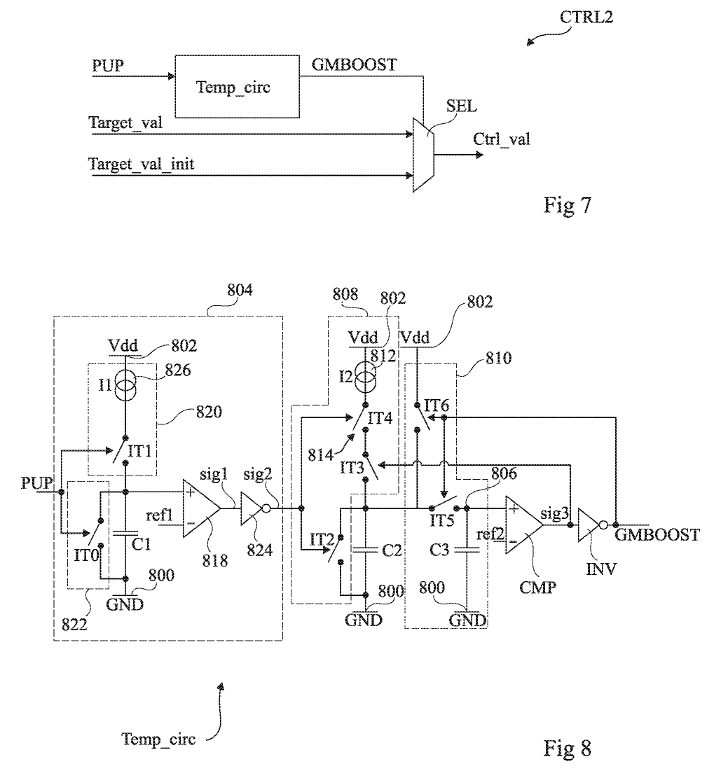

FIG. 7 shows, in the form of blocks, a more detailed example of embodiment of circuit CTRL2.

In the embodiment of FIG. 7, circuit CTRL2 is configured to receive the operating target value Target_val.

In the embodiment of FIG. 7, circuit CTRL2 comprises a circuit Temp_circ.

Circuit Temp_circuit is a time delay circuit. More particularly, circuit Temp_circuit is configured to receive start-up signal PUP, and, as a response to the reception of this signal PUP, that is, as a response to the reception of an indication that a start-up phase of oscillator 1 is beginning, for example because signal PUP switches to its second state, to trigger a time delay of duration equal to the duration Tstart of the start-up phase. Circuit Temp_circ is further configured to switch a binary control signal GMBOOST to a first binary state of signal GMBOOST at the end of time delay Tstart. The switching of signal GMBOOST to its second binary state thus indicates the end of the start-up phase. Preferably, signal GMBOOST is, by default, in a first binary state of signal GMBOOST.

Circuit CTRL2 further comprises a circuit SEL. Circuit SEL is configured to supply control value Ctrl_val equal to the initial target value Target_val_init until the switching of signal GMBOOST to its first state. In other words, when circuit CTRL2 receives the indication of the beginning of a start-up phase via signal PUP, circuit SEL is configured so that value Ctrl_val is equal to value Target_val_init from the time of beginning of the start-up phase until the end of the start-up phase. For example, circuit SEL receives value Target_val_init. For example, circuit SEL receives signal GMBOOST. For example, circuit SEL is configured so that value Ctrl_val is equal to value Target_val_init as long as signal GMBOOST is in its second binary state.

After the switching of signal GMBOOST to its first state to indicate the end of the start-up phase, circuit SEL is further configured to supply value Ctrl_val equal to a value determined by the operating target value Target_val.

In the example shown in FIG. 7, circuit SEL is more particularly configured so that, after the switching of signal GMBOOST to its first state, control value Ctrl_val is equal to the operating target value Target_val received by circuit CTRL2. For example, circuit SEL may then be implemented by a multiplexer circuit. This multiplexer circuit receives values Target_val and Target_val_init on two data inputs of circuit SEL, and signal GMBOOST on a control input of circuit SEL. An output of this multiplexer circuit SEL supplies control value Ctrl_val.

Although this is not detailed in FIG. 7, according to an embodiment, circuit Temp_circ is configured to trigger a charge of a capacitor as a response to the start-up signal, in such a way as to determine the duration Tstart of the start-up phase, and, for example, the end of time delay Tstart, by comparing a voltage across this capacitor with a first voltage reference. The capacitor charge begins, for example, after a brief phase of discharge of this capacitor, this discharge phase being caused by the switching of signal GMBOOST to its first state. As an example, the time required for the voltage across the capacitor to become equal to or greater than the first reference voltage is programmable, for example by programming the value of the first reference voltage or by programming a value of a charge current of the capacitor or by programming the value of this capacitor. Thereby, the value of duration Tstart is programmable.

Preferably, in such an embodiment, advantage is taken of the presence of a power supply decoupling capacitor to implement circuit Temp_circ. Indeed, the use of a capacitor dedicated to the determination of duration Tstart requires providing the surface area needed for the implementation of this capacitor, which increases the surface area of circuit Temp_circ as compared with the case where a power supply decoupling capacitor is used to determine duration Tstart during the start-up phase, and then to decouple a power supply rail from a reference rail once the start-up phase has ended. In this case, circuit Temp_circ is configured to trigger the charge of the decoupling capacitor as a response to start-up signal PUP, to determine the end of time delay Tstart by comparing a voltage across the capacitor (C2) with the first voltage reference, and then to couple the decoupling capacitor between a power supply rail and a reference rail at the end of the time delay. A detailed example of embodiment of circuit Temp_circ allowing this operation is described hereafter in relation with FIG. 8.

As a variant, the determination of time period Tstart by circuit Temp_circuit, that is, the detection that time period Tstart has elapsed, may be implemented in another way than with the charge (or discharge) of a capacitor. For example, time period Tstart time may be assessed by means of a counter clocked by signal sigLO, and time period Tstart, for example, when the counter reaches a threshold, for example programmable.

FIG. 8 shows, in the form of an electronic circuit, a detailed example of the circuit Temp_circuit of FIG. 7 according to an embodiment in which advantage is taken of a power supply decoupling capacitor to determine the end of time period Tstart. In this embodiment, the start-up phase of oscillator 1 begins when signal PUP switches from its second state to its first state.

Circuit Temp_circ comprises a power supply decoupling capacitor C2. Capacitor C2 has an electrode coupled, preferably connected, to a reference rail 800, that is, a conductive rail configured to receive a reference potential GND, for example, ground. When the second electrode of capacitor C2 is coupled to a power supply rail 802, that is, a conductive rail configured to receive a power supply potential Vdd, capacitor C2 enables to decrease voltage variations between rails 800 and 802.

Circuit Temp_circ comprises a circuit 804 (delimited by dotted lines in FIG. 8). Circuit 804 is configured to supply a control signal sig2. Circuit 804 is configured to switch signal sig2 to a first binary state of signal sig2 when signal PUP switches to its first state. Further, circuit 804 is configured to switch signal sig2 to a second binary state of signal sig2 on expiry of a time period Tdis starting with the switching of signal PUP to its second state. Time period Tdis is, for example, short as compared with time period Tstart, for example at least 10 times shorter than time period Tstart.

Circuit Temp_circ further comprises a circuit CMP configured to compare a voltage on a node 806 of circuit Temp_circ with the first reference voltage ref2. For example, circuit CMP has an input connected to node 806, an input receiving voltage ref2, and an output supplying a signal sig3 indicating the result of the comparison. As an example, circuit CMP is an operational amplifier assembled as a comparator having, for example, an inverting input (-) receiving voltage ref2 and a non-inverting input (+) connected to node 806.

Circuit Temp_circ further comprises a circuit 808 (delimited by dotted lines in FIG. 8). Circuit 808 is configured to supply a charge current I2 to capacitor C2 if the voltage of node 806 is lower than voltage ref2 and signal sig2 is in its second binary state, and to bypass capacitor C2 when signal sig2 is in its first binary state. Thus, when signal sig2 is in its first binary state, circuit 808 discharges capacitor C2. Then, when signal sig2 switches to its second binary state, at the end of time period Tdis, capacitor C2 is charged by current I2 until the voltage of node 806 becomes greater than or equal to voltage ref2, after which the charge of capacitor C2 is stopped.

Circuit Temp_circ further comprises a circuit 810 (delimited by dotted lines in FIG. 8).

If the voltage at node 806 is lower than voltage ref2, circuit 810 is configured to couple the second electrode of capacitor C2 to node 806. Thus, when the voltage at node 806 is lower than voltage ref2 and circuit 808 supplies current I2 because signal sig2 is in its second binary state, capacitor C2 charges and the voltage at node 806 increases. The voltage at node 806 increases from a zero value, since during time period Tdis, when signal sig2 is in its first binary state, capacitor C2 is bypassed so as to fully discharge any residual charge which would be stored therein. When circuit 810 couples the second electrode of capacitor C2 to node 806, circuit 810 is configured so that this second electrode of capacitor C2 is isolated from rail 802. Thus, during time period Tdis of discharge of capacitor C2 and during the charge of capacitor C2 up to voltage ref2, capacitor C2 is not used as a power supply decoupling capacitor.

Further, if the voltage at node 806 becomes greater than or equal to voltage ref2, circuit 810 is configured to isolate the second electrode of capacitor C2 from node 806 and to couple this second electrode of capacitor C2 to rail 802. When circuit 810 isolates the second electrode of capacitor C2, circuit 810 is further configured to maintain the voltage at node 806 at its current value. Thus, when the voltage at node 806 becomes greater than or equal to voltage ref2 and the start-up phase of oscillator 1 ends, capacitor C2 resumes its primary function as a power supply decoupling capacitor.

In the circuit Temp_circ of FIG. 8, signal GMBOOST is determined from signal sig3, so that signal GMBOOST switches to its first binary state when the voltage at node 806 becomes greater than or equal to voltage ref2. For example, signal GMBOOST is obtained at the output of an inverter INV receiving signal sig3 on its input.

As an example of implementation, as shown in FIG. 8, circuit 808 comprises a switch IT2 connected in parallel with capacitor C2. Switch IT2 is configured to be switched to the on, respectively off, state by the first binary state, respectively the second binary state, of signal sig2. As an example, when the first binary state of signal sig2 corresponds to a zero voltage and the second binary state of signal sig2 corresponds to power supply voltage Vdd, switch IT2 is, for example, implemented by an N-channel MOS (Metal Oxide Semiconductor) transistor receiving signal sig2 on its gate.

As an example, as shown in FIG. 8, circuit 808 comprises a current source 812 and a switch 814. Switch 814 is connected between current source 812 and the second electrode of capacitor C2. Switch 814 is controlled by signal sig2 and by a signal indicating the result of the comparison of the voltage at node 806 with voltage ref2, for example signal sig3. Switch 812 is configured to couple current source 814 to capacitor C2 when signal sig2 is in its second binary state and, simultaneously, the voltage at node 806 is lower than voltage ref2, and to isolate current source 812 from capacitor C2 when signal sig1 is in its first binary state or the voltage at node 806 is greater than or equal to voltage ref2.

As an example, switch 812 comprises a first switch IT4 controlled by signal sig2 in series with a second switch IT3 controlled by signal sig3. Switch IT4 is on, respectively off, when signal sig2 is in its second binary state, respectively its first binary state, and switch IT3 is on, respectively off, when signal sig3 indicates that the voltage at node 806 is lower than, respectively greater than or equal to, voltage ref2. As an example, when the first binary state of signal sig2 corresponds to a zero voltage and the second binary state of signal sig2 corresponds to power supply voltage Vdd, switch IT4 is, for example, implemented by a P-channel MOS (Metal Oxide Semiconductor) transistor receiving signal sig2 on its gate. As an example, when signal sig3 corresponds to voltage Vdd, respectively to a zero voltage, if the voltage at node 806 is lower than, respectively greater than or equal to, voltage ref2, switch IT3 is, for example, implemented by a P-channel MOS (Metal Oxide Semiconductor) transistor receiving signal sig3 on its gate.

Those skilled in the art will be capable of providing other examples of implementations of circuit 808, for example other examples of implementations of the switch 814 of circuit 808.

As an example of implementation, as shown in FIG. 8, circuit 810 comprises two switches IT6 and IT5 and one capacitor C3. Capacitor C3 is connected between node 806 and node 800 and is used to store the voltage present on node 806 when circuit 810 isolates capacitor C2 from node 806. Capacitor C3 has, for example, a lower value than capacitor C2, for example at least ten times lower than capacitance C2, so that the surface area occupied by capacitor C3 is negligible as compared with that of capacitor C2. Switch IT5 is connected between node 806 and the second electrode of capacitor C2. Switch IT5 is controlled by a signal indicating the result of the comparison of the voltage of node 806 with voltage ref2, for example by signal GMBOOST. Switch IT5 is on, or off, when the voltage at node 806 is lower than, or greater than, or equal to, voltage ref2. Switch IT5 is, for example, implemented by a MOS transistor receiving signal GMBOOST on its gate. Switch IT6 is connected between the second electrode of capacitor C2 and rail 802. Switch IT6 is controlled by a signal indicating the result of the comparison of the voltage of node 806 with voltage ref2, for example by signal sig3. Switch IT6 is off, respectively on, when the voltage on node 806 is lower than, respectively greater than or equal to, voltage ref2. As an example, when signal sig3 corresponds to voltage Vdd, respectively to a zero voltage, if the voltage of node 806 is lower than, respectively greater than or equal to, voltage ref2, switch IT3 is, for example, implemented by a P-channel MOS transistor receiving signal sig3 on its gate.

Those skilled in the art will be capable of providing other examples of implementations of circuit 810.

As an example of implementation, as illustrated in FIG. 8, circuit 804 comprises a capacitor C1, a circuit 818 for comparing the voltage across capacitor C1 with a second reference voltage ref1, a circuit 820 for charging capacitor C1 controlled by signal PUP, and a circuit 822 for discharging capacitor C1 controlled by signal PUP.

Capacitor C1 is connected between rail 800 and an input, for example, non-inverting (+) of circuit 818, circuit 818 being, for example, an operational amplifier connected as a comparator. Capacitor C1 has, for example, a value lower than that of capacitor C2, for example at least ten times lower than that of capacitor C2, so that the surface area occupied by capacitor C1 is negligible as compared with that of capacitor C2. Another input, for example inverting (-), of circuit 818 receives voltage ref1. Circuit 818 is configured to compare the voltage across capacitor C1 with voltage ref1, and to supply a binary signal sig1 indicating the result of this comparison. Signal sig2 is determined by signal sig1. For example, circuit 804 comprises an inverter 824 receiving signal sig1 and supplying signal sig2.

Circuit 822 is configured to discharge capacitor C1 when signal PUP is in its second binary state. For example, circuit 822 comprises a switch IT0 connected in parallel with capacitor C1. Switch IT0 is in the on, respectively off, state when signal PUP is in its second binary state, respectively its first binary state. As an example, when the first binary state of signal PUP corresponds to a zero voltage and the second binary state of signal PUP corresponds to power supply voltage Vdd, switch IT0 is, for example, implemented by an N-channel MOS transistor receiving signal PUP on its gate.

Circuit 820 is configured to charge capacitor C1 when signal PUP is in its first binary state. Circuit 808 comprises, for example, a current source 826 and a switch IT1. Switch IT1 is connected between current source 826 and capacitor C1. Switch IT1 is controlled by signal PUP. Switch IT1 is configured to couple current source 826 to capacitor C1 when signal PUP is in its first binary state, and to isolate current source 826 from capacitor C1 when signal PUP is in its second binary state. Current source 826 is configured to supply a current I1 to charge capacitor C1. As an example, when the first binary state of signal PUP corresponds to a zero voltage and the second binary state of signal PUP corresponds to power supply voltage Vdd, switch IT1 is, for example, implemented by a P-channel MOS transistor receiving signal PUP on its gate.

Those skilled in the art will be capable of providing other examples of implementation of circuit 804, for example other examples of implementation of circuit 820 or of circuit 822.

In the second above-described aspect, at the end of the start-up phase of oscillator 1, control value Ctrl_val switches from value Target_val_init to a value determined by the operating target value Target_val. Now, as previously described in relation with FIGS. 1 and 2, too great a variation in control value Ctrl_val can lead to a loss of oscillations in oscillator 1.

Thus, according to a third aspect, it is provided that, after the implementation of a start-up phase according to the second aspect, the control of the value of capacitor CL is implemented in the way described in the first aspect.

For example, in the third aspect, circuit CTRL2 is modified to add circuit CTRL1 thereto. For example, circuit CTRL1 receives the operating target value Target_val and the value available at the output of circuit CTRL1 is supplied to circuit SEL. As an example, circuit CTRL1 is deactivated for the duration Tstart of the start-up phase, for example by deactivating the clock signal of circuit CTRL1, so that, at the end of the start-up phase, the output value of circuit CTRL1 is not already equal to value Target_val, and that the update of control value Ctrl_val at the output of circuit SEL is performed progressively while keeping ratio gm/gmcrit greater than or equal to 2. As an alternative example, circuit CTRL1 is not deactivated during the start-up phase, but receives as an input the initial target value Target_val_init, and then, at the end of the start-up phase, the operating target value is applied to the input of circuit CTRL1.

Those skilled in the art will be capable of providing other examples of combinations of the first and second aspects, for example by providing for circuit CTRL2 to comprise circuit CTRL1.

More generally, in the combination of the first and second aspects, circuit CTRL2 is configured to implement the start-up phase as previously described according to the second aspect, and, from the end of start-up time period Tstart, to: receive the operating target value Target_val; at each beginning of a period of clock signal Clk, update and store control value Ctrl_val from the internal value Int_val of circuit CTRL1; and at each period of clock signal Clk: - subtract control value Ctrl_val from the operating target value Target_ctrl, - determine the modification value Mod_val equal to the result Res_val of the subtraction if this result Res_val is between thresholds Th1 and Th2, to threshold Th1 if this result Res_val is greater than or equal to threshold Th1, and to threshold Th2 if this result Res_val is lower than or equal to threshold Th2, and - calculate internal value Int_val by adding modification value Mod_val to control value Ctrl_val.

Of course, those skilled in the art will be capable of providing other ways of controlling capacitor CL at the end of the start-up phase according to the second aspect. Conversely, to provide a start-up phase different from that described in the second aspect, for example a start-up phase based on an increase in the bias current of oscillator 1, which is then followed by a control of capacitor CL as described in relation with the first aspect.

For example, knowing the operating target value Target_val that circuit CTRL2 receives from as soon as the end of a start-up phase according to the second aspect, value Target_val_init can be determined on the one hand so that ratio gm/gmcrit is greater than 5 during the start-up phase, and, on the other hand, so that at the end of the start-up phase, when control value Ctrl_val switches from the initial target value Target_val_init to the operating target value Target_val, ratio gm/gmcrit remains greater than or equal to 2.

For example, control circuit CTRL2 is configured so that, from the end of start-up time period Tstart, control value Ctrl_val is equal to the operating target value Target_val, and the circuit supplying target values Target_val and Target_val_init is configured to determine the initial target value Target_val_init from the operating target value Target_val supplied to circuit CTRL2 at the end of the start-up phase, so that when control value Ctrl_val switches from value Target_val_init to value Target_val, ratio gm/gmcrit remains greater than or equal to 2.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. In particular, those skilled in the art will be capable of determining the constant value of transconductance gm to be used to calculate ratio gm/gmcrit. Further, those skilled in the art will be capable of determining the absolute value of thresholds Th1 and Th2 enabling ratio gm/gmcrit to always be greater than or equal to 2 in a change of the value CTRL_val for controlling the value of capacitor CL, for example by taking into account the constant step C0 between the discrete values of capacitor CL, that is, the constant step CL0 = 2.C0 between the discrete values of each of capacitors CL, and the period of signal Clk, that is, the duration of each cycle of signal Clk.

What is claimed is:

1. A circuit for controlling a value of a charge capacitor of a crystal oscillator, the circuit configured to:
receive an operating target value;
at each beginning of a period of a clock signal, update and store a control value of the value of the charge capacitor of a crystal oscillator from an internal value of the circuit; and
at each period of the clock signal:
subtract the control value from the operating target value to produce a subtraction result;
determine a modification value equal to:
the subtraction result when the subtraction result is between a first positive threshold and a second negative threshold,
the first positive threshold when the subtraction result is greater than or equal to the first positive threshold, and
the second negative threshold when the subtraction result is smaller than or equal to the second negative threshold; and
calculate the internal value by adding the modification value to the control value,
wherein the first positive threshold and the second negative threshold have a same absolute value determined so that oscillations of the crystal oscillator are maintained at each update of the control value, the oscillations being maintained when a ratio gm/gmcrit is greater than or equal to 2, with gm being a transconductance of the crystal oscillator and gmcrit being a critical transconductance of the crystal oscillator determined by a current value of the charge capacitor, a frequency of the oscillations, an equivalent series resistance value of a crystal of the crystal oscillator, and a value of a shunt capacitor of the crystal of the crystal oscillator.

2. The circuit according to claim 1, wherein the critical transconductance gmcrit is a minimum value of transconductance gm of the crystal oscillator to obtain oscillations across the crystal oscillator.

3. The circuit according to claim 1, wherein the charge capacitor of the crystal oscillator comprises two identical capacitors with adjustable values, connected to the respective terminals of the crystal of the crystal oscillator.

4. The circuit according to claim 3, wherein the value of each of the two identical capacitors is selected from a plurality of discrete values determined by an adjustment step.

5. The circuit according to claim 1, wherein:
the value of the charge capacitor is selected from a plurality of discrete values, each two successive discrete values of the charge capacitor being separated from each other by a constant step;
the operating target value is equal to one of the discrete values of the charge capacitor; and
the first positive threshold and the second negative threshold have an absolute value equal to an integer multiple of the constant step.

6. The circuit according to claim 1, wherein the operating target value, the control value, the internal value, the subtraction result, and the modification value are digital signals.

7. A device comprising:
a control circuit for controlling a value of a charge capacitor of a crystal oscillator, the control circuit comprising:
a register configured to receive a clock signal and an internal value, and configured to, at each beginning of a period of the clock signal, update and store a control value from the internal value, the control value being supplied to the charge capacitor;
a subtractor configured to subtract the control value from an operating target value to produce a subtraction result;
a saturation circuit configured to receive the subtraction result from the subtractor and to produce a modification value, wherein:
the modification value is equal to the subtraction result when the subtraction result is between a first positive threshold and a second negative threshold,
the modification value is equal to the first positive threshold when the subtraction result is greater than or equal to the first positive threshold, and
the modification value is equal to the second negative threshold when the subtraction result is smaller than or equal to the second negative threshold; and
an adder configured to receive the modification value from the saturation circuit and to add the modification value to the control value to produce the internal value,
wherein the first positive threshold and the second negative threshold have a same absolute value determined so that oscillations of the crystal oscillator are maintained at each update of the control value, the oscillations being maintained when a ratio gm/gmcrit is greater than or equal to 2, with gm being a transconductance of the crystal oscillator and gmcrit being a critical transconductance of the crystal oscillator determined by a current value of the charge capacitor, a frequency of the oscillations, an equivalent series resistance value of a crystal of the crystal oscillator, and a value of a shunt capacitor of the crystal of the crystal oscillator.

8. The device according to claim 7, further comprising a crystal oscillator and a charge capacitor of the crystal oscillator, wherein the control circuit controls the value of the charge capacitor.

9. The device according to claim 7, further comprising:
a crystal oscillator;
a charge capacitor of the crystal oscillator; and
a conversion circuit configured to supply, from a natural binary-coded control value, a gray-coded digital control signal or a thermometric digital control signal to the charge capacitor, wherein the operating target value, the control value, the internal value, the subtraction result, and the modification value are digital signals, and wherein the control value is coded in natural binary.

10. The device according to claim 9, wherein the conversion circuit is configured to supply the gray-coded digital control signal, and wherein the absolute value of the first positive threshold and the second negative threshold is equal to the constant step.

11. The device according to claim 8, wherein the crystal oscillator comprises a crystal and a resistive feedback inverter forming an oscillating loop of the crystal oscillator.

12. A method of controlling a value of a charge capacitor of a crystal oscillator, the method comprising:
receiving, by a control circuit, an operating target value;
at each beginning of a period of a clock signal, updating and storing, by the control circuit, a control value of the value of the charge capacitor from an internal value of the control circuit; and
at each period of the clock signal:
subtracting, by the control circuit, the control value from the operating target value to produce a subtraction result;
determining, by the control circuit, a modification value equal to:
the subtraction result when the subtraction result is between a first positive threshold and a second negative threshold,
the first positive threshold when the subtraction result is greater than or equal to the first positive threshold, and
the second negative threshold when the subtraction result is smaller than or equal to the second negative threshold; and
calculating, by the control circuit, the internal value by adding the modification value to the control value,
wherein the first positive threshold and the second negative threshold have a same absolute value determined so that oscillations of the crystal oscillator are maintained at each update of the control value, the oscillations being maintained when a ratio gm/gmcrit is greater than or equal to 2, with gm being a transconductance of the crystal oscillator and gmcrit being a critical transconductance of the crystal oscillator determined by a current value of the charge capacitor, a frequency of the oscillations, an equivalent series resistance value of a crystal of the crystal oscillator, and a value of a shunt capacitor of the crystal of the crystal oscillator.

13. The method according to claim 12, wherein the critical transconductance gmcrit is a minimum value of the transconductance gm of the crystal oscillator to obtain oscillations across the crystal oscillator.

14. The method according to claim 12, wherein the charge capacitor of the crystal oscillator comprises two identical capacitors with adjustable values, connected to respective terminals of the crystal of the crystal oscillator.

15. The method according to claim 14, wherein a value of each of the two identical capacitors is selected from a plurality of discrete values determined by an adjustment step.

16. The method according to claim 12, wherein:
the value of the charge capacitor is selected from a plurality of discrete values, each two successive discrete values of the charge capacitor being separated from each other by a constant step;
the operating target value is equal to one of the discrete values of the charge capacitor; and
the first positive threshold and the second negative threshold have an absolute value equal to an integer multiple of the constant step.

17. The method according to claim 12, wherein the operating target value, the control value, the internal value, the subtraction result, and the modification value are digital signals.

18. The method according to claim 16, wherein:
the operating target value, the control value, the internal value, the subtraction result, and the modification value are digital signals; and
the control value is coded in natural binary, the method further comprising converting, by a conversion circuit of the control circuit, the natural binary-coded control value into a gray-coded digital control signal or a thermometric digital control signal supplied to the charge capacitor.

19. The method according to claim 18, wherein the conversion circuit supplies the gray-coded digital control signal, and wherein the absolute value of the first positive threshold and the second negative threshold is equal to the constant step.

20. The method according to claim 12, wherein the crystal oscillator comprises the crystal and a resistive feedback inverter forming an oscillating loop of the crystal oscillator.
